(19) United States
(12) Patent Application Publication
(10) Pub. No.: US 2025/0132231 A1
(43) Pub. Date: Apr. 24, 2025

(54) SLOTTED CLIPS FOR REDUCTION OF MOLDING COMPOUND DELAMINATION

(71) Applicant: SEMICONDUCTOR COMPONENTS INDUSTRIES, LLC, Scottsdale, AZ (US)

(72) Inventors: Jie CHANG, Suzhou (CN); Jonghwan BAEK, Gimpo-city (KR); Keunhyuk LEE, Suzhou (CN)

(73) Assignee: SEMICONDUCTOR COMPONENTS INDUSTRIES, LLC, Scottsdale, AZ (US)

(21) Appl. No.: 18/489,961

(22) Filed: Oct. 19, 2023

(51) Int. Cl. H01L 23/495; H01L 23/373

(52) U.S. Cl. CPC H01L 23/49544; H01L 23/3735; H01L 23/49575; H01L 2224/32245; H01L 2924/183; H01L 2924/35121

(57) ABSTRACT

In a general aspect, a semiconductor device assembly includes a substrate, a semiconductor die coupled to the substrate, and a conductive clip coupled to the semiconductor die. The conductive clip is arranged along a longitudinal axis and a transverse axis. The conductive clip has a length along the longitudinal axis, a width along the transverse axis, and a slot defined therethrough. The slot has a length along the longitudinal axis that is greater than or equal to seventy percent of the length of the conductive clip along the longitudinal axis. The slot has a width along the transverse axis that is greater than or equal to thirty percent of the width of the conductive clip along the transverse axis.

### TECHNICAL FIELD

This description relates to molded packages (e.g., modules) for semiconductor device assemblies.

### BACKGROUND

Prior semiconductor device packages, such as power device modules, experience delamination of molding compound from a substrate of the package in an area under a conductive clip of the package. This delamination can be caused by moisture and/or thermal cycling of the semiconductor module, and can lead to failure of the device, e.g., corrosion, die cracking, solder joint failure, etc.

### SUMMARY

In a general aspect, a semiconductor device assembly includes a substrate, a semiconductor die coupled to the substrate, and a conductive clip coupled to the semiconductor die. The conductive clip is arranged along a longitudinal axis and a transverse axis. The conductive clip has a length along the longitudinal axis, a width along the transverse axis, and a slot defined therethrough. The slot has a length along the longitudinal axis that is greater than or equal to seventy percent of the length of the conductive clip along the longitudinal axis. The slot has a width along the transverse axis that is greater than or equal to thirty percent of the width of the conductive clip along the transverse axis.

In another general aspect, a semiconductor device assembly includes a substrate, a semiconductor die coupled to the substrate, and a conductive clip coupled to the semiconductor die. The conductive clip has a length and a width defining an area of a footprint of the conductive clip. The conductive clip has at least one opening defined therethrough. The at least one opening has an area within the area of the footprint of the conductive clip. The area of the at least one opening is greater than or equal to twenty percent of the area of the footprint of the conductive clip.

In another general aspect, a method for producing a semiconductor device assembly includes coupling a semiconductor die with a substrate and coupling a conductive clip with the semiconductor die. The conductive clip includes a slot defined therethrough. The slot has an area that is at least twenty percent of an area of a footprint of the conductive clip. The method further includes forming a wire bond with the semiconductor die, and applying an adhesion promoting material to the semiconductor die, the substrate, the conductive clip and the wire bond. The method also includes performing a molding process to encapsulate the semiconductor die and the conductive clip in a molding compound, and at least partially encapsulate the substrate in the molding compound.

### BRIEF DESCRIPTION OF DRAWINGS

FIG. 1 is a scanning acoustic tomography (SAT) image illustrating delamination of molding compound from a substrate of a molded semiconductor device assembly with a conductive clip after reliability testing.

FIGS. 2A through 2D are diagrams illustrating example semiconductor device assembles implemented with slotted conductive clips.

FIG. 3 is a diagram illustrating an example of a slotted conductive clip, such as the slotted conductive clip in the example of FIG. 2D.

FIG. 4 is a SAT image illustrating absence of molding compound delamination for an implementation of the semiconductor device assembly of FIG. 2C after reliability testing.

FIGS. 5A through 5F are graphs illustrating comparisons of electrical performance parameters for implementations of the molded semiconductor devices of FIGS. 2C and 2D, and a prior molded semiconductor device implementation.

FIG. 6 is a flowchart illustrating an example method of producing a molded semiconductor device assembly, such as the example implementations described herein.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

Power modules (assemblies, semiconductor device assemblies, semiconductor device modules, etc.) can include a direct-bonded metal (DBM) substrate, such as a direct-bonded copper (DBC) substrate. A DBM or DBC substrate can include a ceramic material layer with direct-bonded metal (e.g., patterned metal layer(s)) disposed on at least one side of the ceramic material layer. One or more semiconductor die can be disposed on a first direct-bonded metal layer portion of the substrate, and a conductive clip can be coupled with the semiconductor die, a second direct bonded metal portion of the substrate, and/or a power terminal or a signal terminal. Additional elements can be included, such as wire bonds, and/or a leadframe that includes one or more signal leads, one or more power terminals, etc.

In some implementations, such a semiconductor device assembly or module can be molded, e.g., transfer molded, with an epoxy molding compound to encapsulate at least the semiconductor die, the conductive clip, and a portion of the substrate, e.g., a portion of the substrate on which the semiconductor die and the conductive clip are coupled. Other surfaces of the substrate can be exposed through the molding compound, such as a surface of a direct-bonded metal layer disposed on an opposite side of a ceramic material, e.g., of a DBM substrate, from the semiconductor die. In some implementations, a heat sink, or other cooling mechanism can be coupled to such an exposed surface of a DBM substrate.

Prior clip designs (e.g., solid-bodied, or nearly solid-bodied clips) inhibit a flow of molding compound flow under the clip during a molding process, e.g., a transfer molding process. Further, prior clip designs prevent application of an adhesion promoting substance (e.g., a hydroxyl group containing substance) to portions of a substrate and/or a semiconductor die under the conductive clip, where the adhesion promoting substance improves adhesion of the molding compound to the substrate, the semiconductor die, the conductive clip, and/or one more wire bonds. At least these factors can result in voiding and/or delamination of the molding compound from, at least, the corresponding substrate surface and/or semiconductor die surface, as has been shown by reliability moisture testing and/or thermal cycling testing. Such voiding and/or delamination can then result in damage to the semiconductor die, damage to solder connections between the conductive clip and the substrate, damage to solder connections between the conductive clip and the semiconductor die, and so forth, which can lead to functional failure of an associated semiconductor device module.

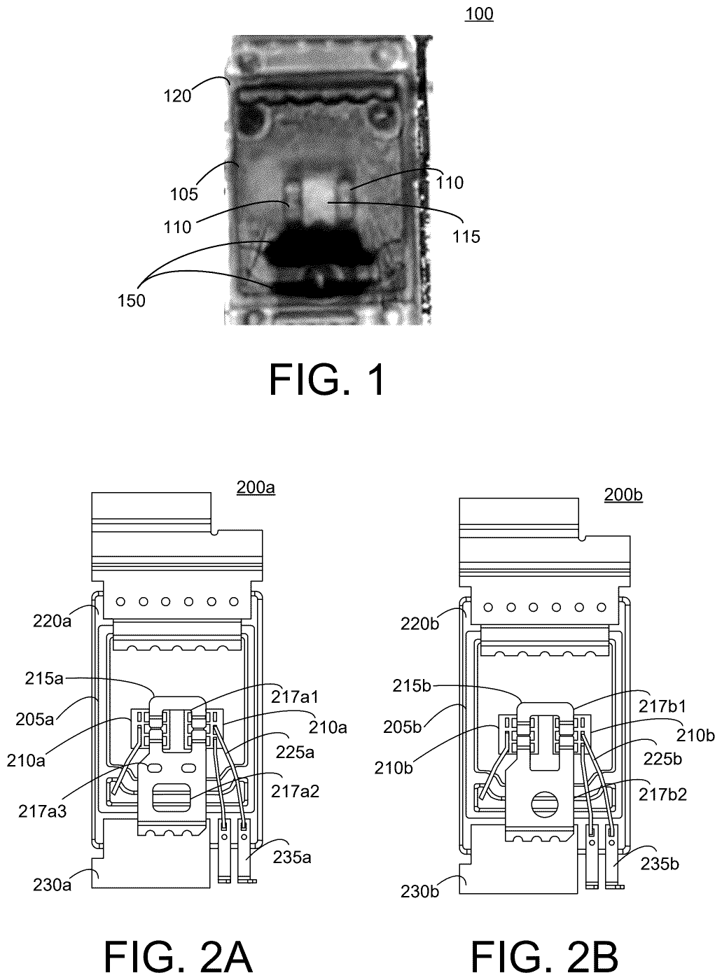

FIG. 1 is a scanning acoustic tomography (SAT) image illustrating delamination of molding compound from a substrate of a molded semiconductor device assembly 100 after reliability testing (e.g., temperature cycling). Accordingly, the image of the molded semiconductor device assembly 100 in FIG. 1 is a through-image (e.g., with internal components being visible).

As shown in FIG. 1, the molded semiconductor device assembly 100 includes a DBM substrate 105, semiconductor die 110 (two semiconductor die) that are disposed on the DBM substrate 105 (e.g., on a patterned metal layer of the DBM substrate 105). The molded semiconductor device assembly 100 further includes a conductive clip 115, which is a solid bodied clip that can be made from copper, an alloy of copper, a metal other than copper, or another metallic alloy.

The molded semiconductor device assembly 100 further includes a molding compound 120, which can be an epoxy molding compound. In some implementations, the molding compound 120 can be applied to the molded semiconductor device assembly 100 using a transfer molding process, an injection molding process, etc. A cure operation can be performed to cure the molding compound 120 after its application to the molded semiconductor device assembly 100, where the molding compound 120 protects other elements of the molded semiconductor device assembly 100 from damage and/or exposure to ambient conditions. For instance, such as described above, the molding compound 120 can encapsulate at least the semiconductor die 110, the conductive clip 115, and a portion of the DBM substrate 105.

The SAT image of the molded semiconductor device assembly 100 in FIG. 1 was obtained after thermal cycling reliability testing of the molded semiconductor device assembly 100 (e.g., repeatedly cycling an ambient temperature of the molded semiconductor device assembly 100 between −65° Celsius (C) and 150° C.). As shown in FIG. 1, as a result of the thermal cycling testing, delamination 150 (and/or voiding) of the molding compound 120 from the DBM substrate 105 is shown by shadowing in the SAT image of the molded semiconductor device assembly 100. The delamination 150, as noted above, can cause damage to elements of the molded semiconductor device assembly 100, such as the semiconductor die 110, solder connections between the semiconductor die 110 and the conductive clip 115, etc. This damage can then cause functional failure of the molded semiconductor device assembly 100 (e.g., improper operation of the semiconductor die 110 and/or the molded semiconductor device assembly 100). The delamination 150 can occur due to poor adhesion of the molding compound 120 to the DBM substrate 105, e.g., due to absence of an adhesion promoter on the DBM substrate 105 under the conductive clip 115, and/or due to poor flow of the molding compound 120 under the conductive clip 115 during the molding process.

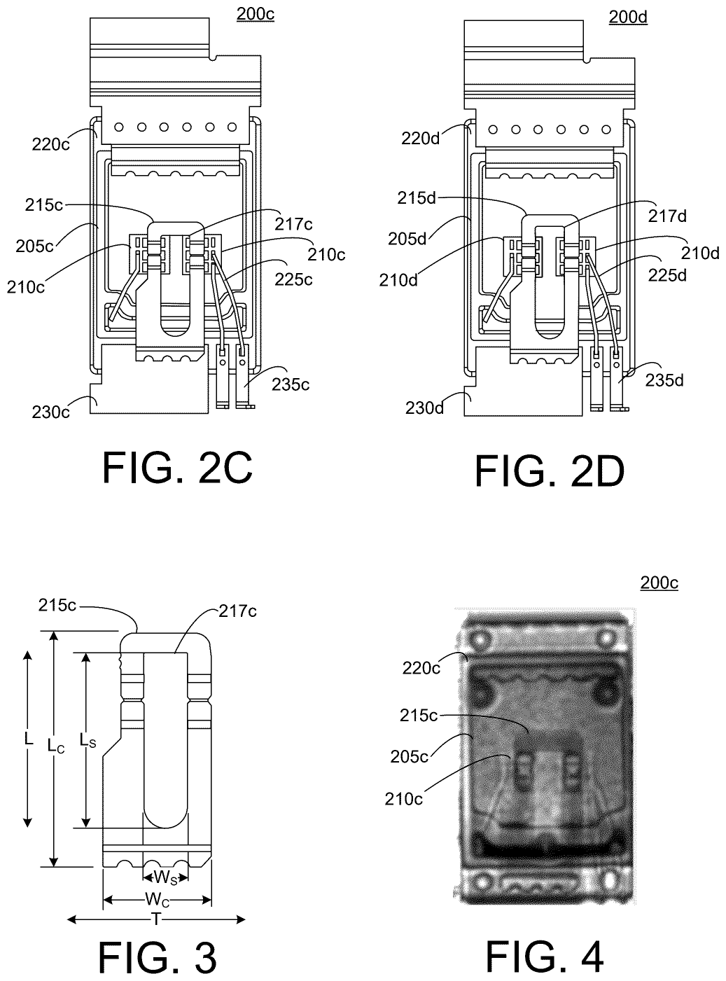

FIGS. 2A through 2D are diagrams illustrating example semiconductor device assembles implemented with slotted conductive clips, which can reduce and/or prevent molding compound delamination and/or voiding, such as illustrated in FIG. 1. For instance, in the examples of FIGS. 2A through 2D, the slotted clips allow for application of an adhesion promoting material (e.g., a hydroxyl group containing substance) to portions of corresponding substrates and semiconductor die that are disposed under a conductive clip, which previous clip implementations obstruct. Further, the slotted clips shown in FIGS. 2A to 2D also allow for improved flow of a molding compound (e.g., in liquid form, prior to a curing operation) during a molding processes, such as transfer molding, such as through the slots. Accordingly, the example implementations of FIGS. 2A through 2D facilitate improved molding compound coverage and adhesion in areas of a semiconductor module that are susceptible to molding compound delamination and/or voiding. That is, coverage of a portion of a molding compound of a semiconductor device assembly disposed between a substrate and a conductive clip can be improved due to molding compound flowing through slot(s) of a slotted conductive clip. Further molding compound, after curing, with the slots can provide mechanical strength that helps prevent molding compound delamination.

As used herein, the term slot refers an opening, through-hole, aperture, etc., that is defined in conductive material (e.g., electrically conductive material) used for a conductive clip. Accordingly, as used herein, a slotted conductive clip refers to a conductive clip that has one or more through holes, openings, apertures, etc. defined therein. In some implementations, a slot can be square-shaped, rectangle-shaped, circle-shaped, oval-shaped, or have other shapes. For instance, a slot of a slotted conductive clip can be generally rectangular shaped, with the slot being semi-circular at one end, and square cornered at an opposite end, such as in the examples of FIG. 2C and FIG. 2D. Each slot, of one or more slots of a slotted clip, has an area that is defined within an area of a footprint (e.g., with the outer perimeter) of a corresponding conductive clip. Furthermore, as the examples of FIGS. 2A through 2D include a number of similar aspects, for purpose of brevity, the details of those similar aspects are not repeated with respect to each of those examples.

FIG. 2A is a diagram that illustrates an example semiconductor device assembly 200a. As with the SAT image of the molded semiconductor device assembly 100 in FIG. 1, the semiconductor device assembly 200a in FIG. 2 is illustrated as a through-view, where internal elements of the semiconductor device assembly 200a (e.g., that would not be visible in an actual device) are shown. In this example, the semiconductor device assembly 200a includes a DBM substrate 205a, and semiconductor die 210a (two semiconductor die) that are disposed on the DBM substrate 205a (e.g., on a patterned metal layer of the DBM substrate 205a). The semiconductor device assembly 200a further includes a slotted conductive clip 215a, which can be made from copper, an alloy of copper, a metal other than copper, or another metallic alloy.

In this example, the slotted conductive clip 215a has a slot 217al, a slot 217a2 and slots 217a3 defined therein. As described herein, the slot 217al, the slot 217a2, and the slots 217a3 can facilitate application of an adhesion promoting material to portions of the DBM substrate 205a and/or the semiconductor die 210a disposed under (in this view) the slotted conductive clip 215a. For instance, an adhesion promoting material can be sprayed through the slot 217al, the slot 217a2, and/or the slots 217a3 onto those portions of the DBM substrate 205a and the semiconductor die 210a.

As can be seen in FIG. 2A, each of the slot 217al, the slot 217a2, and the slots 217a3 has a respective area that is within an area of a footprint of the slotted conductive clip 215a (an area associated with an outer perimeter of the slotted conductive clip 215a). In some implementations, such as the example of FIG. 2A, a sum of the respective areas of the slot 217al, the slots 217a2, and the slots 217a3 (e.g., an aggregate area of the slots) is greater than or equal to twenty percent of the area of the footprint of the slotted conductive clip 215a.

As shown in FIG. 2A, the semiconductor device assembly 200a further includes a molding compound 220a, which can be an epoxy molding compound. In some implementations, the molding compound 220a can be applied to the semiconductor device assembly 200a using a transfer molding process, an injection molding process, etc. A cure operation can be formed to cure the molding compound 220a, which protects other elements of the semiconductor device assembly 200a. For instance, such as described above, the molding compound 220a can encapsulate at least the semiconductor die 210a, the slotted conductive clip 215a, and a portion of the DBM substrate 205a.

The semiconductor device assembly 200a of this example also includes wire bonds 225a, a power supply terminal 230a, and signal terminals 235a. The wire bonds 225a can be used to couple the power supply terminal 230a with the DBM substrate 205a and/or the semiconductor die 210a, and the slotted conductive clip 215a can be further coupled with the power supply terminal 230a. For instance, in this example, the semiconductor die 210a can include respective power field-effect transistors (FETs), such as n-channel FETs (NFETs) that are coupled in parallel with each other. That is, in this example (and in the examples of FIGS. 2B, 2C and 2D), respective drain terminals of the semiconductor die 210a are coupled with the DBM substrate 205a, respective source terminals of the semiconductor die 210a are coupled with the power supply terminal 230a via the slotted conductive clip 215a, and the wire bonds 225a couple gate terminals of the semiconductor die 210a with one of the signal terminals 235a, and a source sense terminal with the other signal terminal 235a shown in FIG. 2. As the example implementations of FIGS. 2B through 2D are illustrated as implementing a same circuit as describe with respect to FIG. 2A, those details are not repeated again with respect to FIGS. 2B through 2D.

FIG. 2B illustrates a through-view of a semiconductor device assembly 200b. In this example, the semiconductor device assembly 200b includes a DBM substrate 205b, semiconductor die 210b (two semiconductor die), a slotted conductive clip 215b, a molding compound 220b, wire bonds 225b, a power supply terminal 230a, and signal terminals 235b. As noted above, similar details of the semiconductor device assembly 200b with details of the semiconductor device assembly 200a in FIG. 2A are not repeated again with respect to the semiconductor device assembly 200b illustrated in FIG. 2B.

In this example, the slotted conductive clip 215b has a slot 217b1 and a slot 217b defined therein. As described herein, the slot 217b1 and the slot 217b2 can facilitate application of an adhesion promoting material to portions of the DBM substrate 205b and/or the semiconductor die 210b disposed under (in this view) the slotted conductive clip 215b. For instance, an adhesion promoting material can be sprayed through the slot 217b1 and the slot 217b2 onto those portions of the DBM substrate 205b and the semiconductor die 210b.

As can be seen in FIG. 2B, each of the slot 217b1 and the slot 217b2 has a respective area that is within an area of a footprint of the slotted conductive clip 215b (an area associated with an outer perimeter of the slotted conductive clip 215b). In some implementations, as the example of FIG. 2B, a sum of the respective areas of the slot 217b1 and the slot 217b2 (e.g., an aggregate area of the slots) is greater than or equal to twenty percent of the area of the footprint of the slotted conductive clip 215b.

FIG. 2C illustrates a through-view of a semiconductor device assembly 200c. In this example, the semiconductor device assembly 200c includes a DBM substrate 205c, semiconductor die 210c (two semiconductor die), a slotted conductive clip 215c, a molding compound 220c, wire bonds 225c, a power supply terminal 230c, and signal terminals 235c. As noted above, similar details of the semiconductor device assembly 200c with details of the semiconductor device assembly 200a in FIG. 2A are not repeated again with respect to the semiconductor device assembly 200c illustrated in FIG. 2C.

In this example, the slotted conductive clip 215c has a slot 217c defined therein, where the slot 217c is a continuous (unbroken, single slot). That is, the slotted conductive clip 215c includes a conductive material (copper, a copper alloy, etc.) that defines a surround (a perimeter, etc.) for the slot 217c. As described herein, the slot 217c can facilitate application of an adhesion promoting material to portions of the DBM substrate 205c and/or the semiconductor die 210c disposed under (in this view) the slotted conductive clip 215c. For instance, an adhesion promoting material can be sprayed through the slot 217c onto those portions of the DBM substrate 205c and the semiconductor die 210c.

As can be seen in FIG. 2C, the slot 217c has a respective area that is within an area of a footprint of the slotted conductive clip 215c (an area associated with an outer perimeter of the slotted conductive clip 215c). In some implementations, the area of the slot 217c is greater than or equal to twenty percent of the area of the footprint of the slotted conductive clip 215c.

FIG. 2D illustrates a through-view of a semiconductor device assembly 200d. In this example, the semiconductor device assembly 200d includes a DBM substrate 205d, semiconductor die 210d (two semiconductor die), a slotted conductive clip 215d, a molding compound 220d, wire bonds 225d, a power supply terminal 230a, and signal terminals 235d. As noted above, similar details of the semiconductor device assembly 200d with details of the semiconductor device assembly 200a in FIG. 2A are not repeated again with respect to the semiconductor device assembly 200d illustrated in FIG. 2D.

In this example, the slotted conductive clip 215d has a slot 217d defined therein, where the slot 217d is a continuous (unbroken, single slot). That is, the slotted conductive clip 215d includes a conductive material (copper, a copper alloy, etc.) that defines a surround (a perimeter, etc.) for the slot 217d. As described herein, the slot 217d can facilitate application of an adhesion promoting material to portions of the DBM substrate 205d and/or the semiconductor die 210d disposed under (in this view) the slotted conductive clip 215d. For instance, an adhesion promoting material can be sprayed through the slot 217d onto those portions of the DBM substrate 205d and the semiconductor die 210d.

As can be seen in FIG. 2D, the slot 217d has a respective area that is within an area of a footprint of the slotted conductive clip 215d (an area associated with an outer perimeter of the slotted conductive clip 215d). In some implementations, the area of the slot 217d is greater than or equal to twenty percent of the area of the footprint of the slotted conductive clip 215d. As compared with the slotted conductive clip 215c, the slotted conductive clip 215d can have a height along a line H that is greater than a height of the slotted conductive clip 215c. Furthermore, the slot 217d can have a length along the line H that is greater than a length of the slot 217c along the line H. In some implementations, a slot slotted conductive clip can have a slot with different widths (transvers to the line H) than those illustrated in FIGS. 2C and 2D for the slot 217c and the slot 217d, respectively.

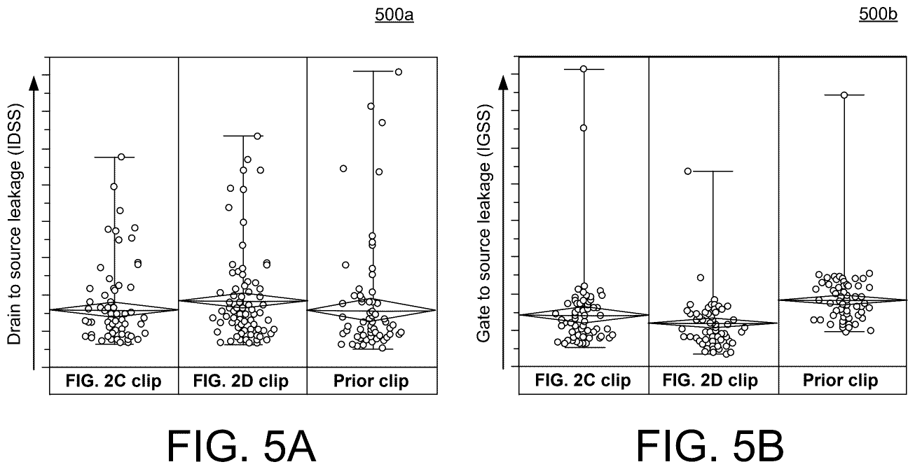

FIG. 3 is a diagram illustrating an example of a slotted conductive clip, such as the slotted conductive clip 215c of the semiconductor device assembly 200c illustrated in FIG. 2C. While the specific dimensions may vary, the discussion of the slotted conductive clip 215c below can similarly apply to implementations of the slotted conductive clip 215d shown FIG. 2D.

As shown in FIG. 3, the slotted conductive clip 215c can be arranged along a longitudinal axis L and a transverse axis T. That is, the clip slotted conductive clip 215c can be arranged, at least in part, in a plane that is defined by the longitudinal axis L and the transverse axis T. In this example, as shown in FIG. 3, the slotted conductive clip 215c has a length L_{C} along the longitudinal axis L, and a width W_{C} along the transverse axis T. As further shown in FIG. 3, the slot 217c of the slotted conductive clip 215c has a length L_{S} along the longitudinal axis L, and a width W_{S} along the transverse axis T. In some implementations the length L_{S} of the slot 217c can be greater than or equal to seventy percent of the length L_{C} of the slotted conductive clip 215c. Furthermore, in some implementations, such as this example, the width W_{S} of the slot 217c can be greater than or equal to thirty percent of the width W_{C} of the slot slotted conductive clip 215c.

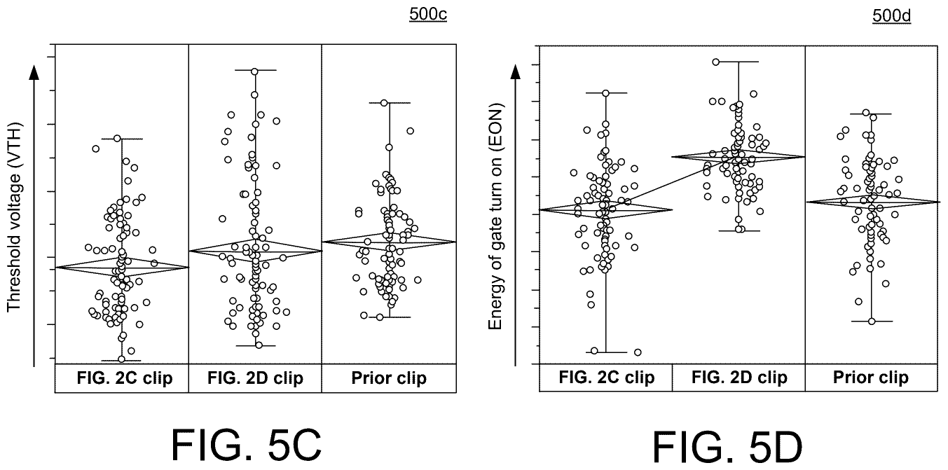

FIG. 4 is a SAT image illustrating absence of molding compound delamination for an implementation of the semiconductor device assembly 200c of FIG. 2C after reliability testing. In this example, the semiconductor device assembly 200c was subjected to temperature cycling reliability testing, as with the molded semiconductor device assembly 100 of FIG. 1. As can be seen in FIG. 4, as compared to FIG. 1, shadowing indicating delamination (and/or voiding) of the molding compound 220c from the DBM substrate 205c is absent in FIG. 4, indicating that molding compound delamination has been significantly reduced or eliminated. That is, as the slot 217c in the slotted conductive clip 215c allows for improved molding compound flow under the clip, e.g., between the clip and the substrate, and improved adhesion promoter coverage, the occurrence of delamination as a result of such reliability testing is reduced and/or prevented, as is shown by the SAT image in FIG. 4.

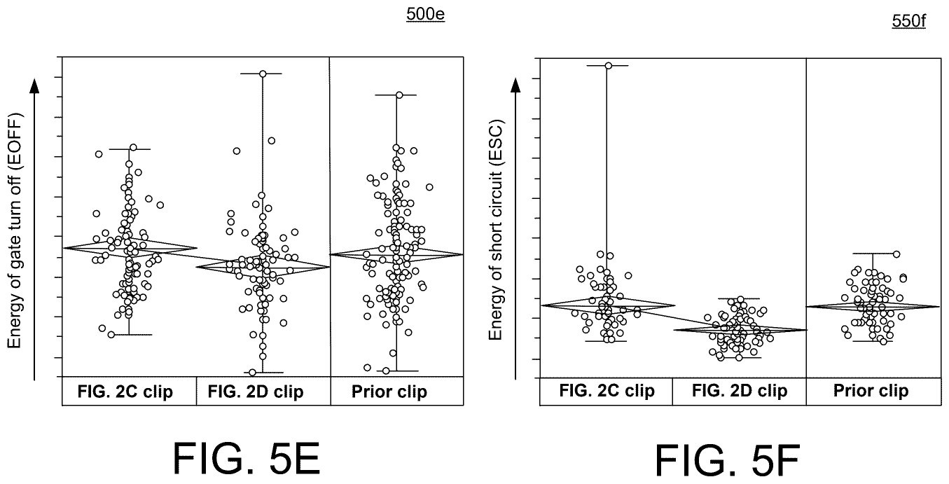

FIGS. 5A through 5F are graphs illustrating comparisons of normalized electrical performance parameters for example implementations of the molded semiconductor devices of FIGS. 2C and 2D, with a prior molded semiconductor device implementation including a full-bodied conductive clip (e.g., excluding slots). FIGS. 5A to 5F illustrate that use of a slotted conductive clip, such the example clips of FIGS. 2C and 2D, has negligible, or insignificant effect on electrical performance parameters of implementations of an example power module. In the examples of FIGS. 5A through 5F, a power module with a power transistor pair, coupled in parallel, with a common gate terminal was tested. Specifically, a power module with a prior clip was compared with power modules respectively including implementations of the respective slotted conductive clips 215c and 215d of FIGS. 2C and 2D, as is indicated in each of FIGS. 5A to 5F.

Specifically, FIG. 5A is a graph 500a that illustrates scatterplots comparing drain to source leakage of prior implementation devices, with the implementations of the semiconductor device assembly 200c and the semiconductor device assembly 200d. FIG. 5B is a graph 500b that illustrates scatterplots comparing gate to source leakage of prior implementation devices, with the implementations of the semiconductor device assembly 200c and the semiconductor device assembly 200d. FIG. 5C is a graph 500c that illustrates scatterplots comparing threshold voltage of prior implementation devices, with the implementations of the semiconductor device assembly 200c and the semiconductor device assembly 200d. FIG. 5D is a graph 500d illustrating scatterplots comparing energy for gate turn-on of prior implementation devices, with the implementations of the semiconductor device assembly 200c and the semiconductor device assembly 200d. FIG. 5E is a graph illustrating scatterplots comparing energy for gate turn-off of prior implementation devices, with the implementations of the semiconductor device assembly 200c and the semiconductor device assembly 200d. FIG. 5F is a graph 500f illustrating scatterplots comparing short-circuit energy of prior implementation devices, with the implementations of the semiconductor device assembly 200c and the semiconductor device assembly 200d. Further, measurements of parasitics of the modules used to obtain the results of FIG. 5 showed negligible differences, e.g., zero to three percent variation in parasitic inductance measurements, and a one percent decrease in gate capacitance.

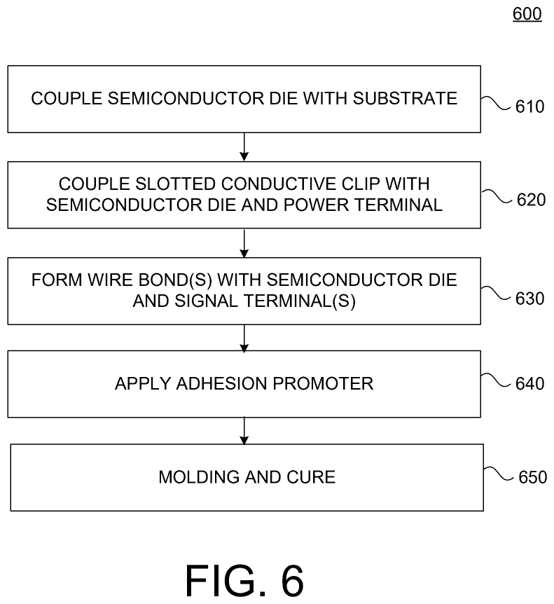

FIG. 6 is a flowchart illustrating an example method 600 of producing a molded semiconductor device assembly, such as the example implementations assemblies described herein. As shown in FIG. 6, at block 610, the method 600 includes coupling at least one semiconductor die with a substrate. For instance, the at least one semiconductor die can be soldered, sintered, etc. to a patterned metal layer of a DBM substrate. At block 620, the method includes coupling a slotted conductive clip with the semiconductor die and a power terminal of a leadframe, which can include soldering the clip to the semiconductor die and the power terminal. At block 620, depending on the particular implementation, the slotted conductive clip can also be coupled to the substrate (e.g., for electrical connection to a circuit of the assembly and/or for mechanical support). At block 630, the method 600 includes forming at least one wire bond between the semiconductor die and respective signal terminals of a leadframe. In some implementations, one or more wire bonds can also be coupled to the substrate, e.g., to a gate connection bus. At block 640, the method includes applying (spraying, etc.) an adhesion promoter, which includes applying (spraying) the adhesion promoter through one or more slots defined in the slotted conductive clip. At block 650, the method 600 includes performing molding and cure operations, e.g., to encapsulate the semiconductor device assembly, such as in the examples described herein.

In a general aspect, a semiconductor device assembly includes a substrate, a semiconductor die coupled to the substrate, and a conductive clip coupled to the semiconductor die. The conductive clip is arranged along a longitudinal axis and a transverse axis. The conductive clip has a length along the longitudinal axis, a width along the transverse axis, and a slot defined therethrough. The slot has a length along the longitudinal axis that is greater than or equal to seventy percent of the length of the conductive clip along the longitudinal axis. The slot has a width along the transverse axis that is greater than or equal to thirty percent of the width of the conductive clip along the transverse axis.

Implementations can include one or more of the following features or aspects, alone or in combination. For example, the slot in the conductive clip can be a continuous slot.

The conductive clip can include an electrically conductive material that defines a surround of the slot.

The semiconductor device assembly can include a molding compound encapsulating the semiconductor die and the conductive clip, and at least partially encapsulating the substrate. A first portion of the molding compound can be disposed between the conductive clip and the substrate, and a second portion of the molding compound can be disposed in the slot.

The semiconductor device assembly can include a leadframe having a power terminal. The conductive clip can be further coupled to the power terminal. The leadframe can include a signal terminal that is electrically coupled with the semiconductor die via a wire bond. The semiconductor die can include a field-effect transistor (FET). The conductive clip can be coupled with a source terminal of the FET. A drain terminal of the FET can be coupled with the substrate. The wire bond can be coupled with a gate terminal of the FET.

In another general aspect, a semiconductor device assembly includes a substrate, a semiconductor die coupled to the substrate, and a conductive clip coupled to the semiconductor die. The conductive clip has a length and a width defining an area of a footprint of the conductive clip. The conductive clip has at least one opening defined therethrough. The at least one opening has an area within the area of the footprint of the conductive clip. The area of the at least one opening is greater than or equal to twenty percent of the area of the footprint of the conductive clip.

Implementations can include one or more of the following features or aspects, alone or in combination. For example, the at least one opening in the conductive clip can be a continuous slot. The conductive clip can include an electrically conductive material that defines a surround of the continuous slot.

The at least one opening in the conductive clip can include a plurality of openings in the conductive clip. The area of the at least one opening can be an aggregate of respective areas of the plurality of openings.

The semiconductor device assembly can include a molding compound encapsulating the semiconductor die and the conductive clip, and at least partially encapsulating the substrate. A first portion of the molding compound can be disposed between the conductive clip and the substrate. A second portion of the molding compound can be disposed in the at least one opening.

The semiconductor device assembly can include a leadframe including a power terminal. The conductive clip can be further coupled to the power terminal. The leadframe can include a signal terminal that is electrically coupled with the semiconductor die via a wire bond. The semiconductor die can include a field-effect transistor (FET). The conductive clip can be coupled with a source terminal of the FET. A drain terminal of the FET can be coupled with the substrate. The wire bond can be coupled with a gate terminal of the FET.

In another general aspect, a method for producing a semiconductor device assembly includes coupling a semiconductor die with a substrate and coupling a conductive clip with the semiconductor die. The conductive clip includes a slot defined therethrough. The slot has an area that is at least twenty percent of an area of a footprint of the conductive clip. The method further includes forming a wire bond with the semiconductor die, and applying an adhesion promoting material to the semiconductor die, the substrate, the conductive clip and the wire bond. The method also includes performing a molding process to encapsulate the semiconductor die and the conductive clip in a molding compound, and at least partially encapsulate the substrate in the molding compound.

Implementations can include one or more of the following features or aspects, alone or in combination. For example, applying the adhesion promoting material can include spraying the adhesion promoting material. Applying the adhesion promoting material can include applying the adhesion promoting material to a portion of the substrate and a portion of the semiconductor die by spraying the adhesion promoting material through the slot.

The method can include further coupling the conductive clip with a power terminal of a leadframe.

Forming the wire bond with the semiconductor die can include electrically coupling the semiconductor die with a signal terminal of a leadframe via the wire bond.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly, comprising:
a substrate;
a semiconductor die coupled to the substrate; and
a conductive clip coupled to the semiconductor die, the conductive clip having a length and a width defining an area of a footprint of the conductive clip,
the conductive clip having at least one opening defined therethrough, the at least one opening having an area within the area of the footprint of the conductive clip, the area of the at least one opening being greater than or equal to twenty percent of the area of the footprint of the conductive clip.

2. The semiconductor device assembly of claim 1, wherein the at least one opening in the conductive clip is a continuous slot.

3. The semiconductor device assembly of claim 2, wherein the conductive clip includes an electrically conductive material that defines a surround of the continuous slot.

4. The semiconductor device assembly of claim 1, wherein:
the at least one opening in the conductive clip includes a plurality of openings in the conductive clip; and
the area of the at least one opening is an aggregate of respective areas of the plurality of openings.

5. The semiconductor device assembly of claim 1, further comprising a molding compound encapsulating the semiconductor die and the conductive clip, and at least partially encapsulating the substrate.

6. The semiconductor device assembly of claim 5, wherein:
a first portion of the molding compound is disposed between the conductive clip and the substrate, and
a second portion of the molding compound is disposed in the at least one opening.

7. The semiconductor device assembly of claim 1, further comprising a leadframe including a power terminal, the conductive clip being further coupled to the power terminal,
wherein:
the leadframe further includes a signal terminal that is electrically coupled with the semiconductor die via a wire bond;
the semiconductor die includes a field-effect transistor (FET);
the conductive clip is coupled with a source terminal of the FET;
a drain terminal of the FET is coupled with the substrate; and
the wire bond is coupled with a gate terminal of the FET.

8. A semiconductor device assembly, comprising:
a substrate;
a semiconductor die coupled to the substrate; and
a conductive clip coupled to the semiconductor die and having:
a length along a longitudinal axis;
a width along a transverse axis; and
a slot defined therethrough, the slot having:
a length along the longitudinal axis that is greater than or equal to seventy percent of the length of the conductive clip along the longitudinal axis; and
a width along the transverse axis that is greater than or equal to thirty percent of the width of the conductive clip along the transverse axis.

9. The semiconductor device assembly of claim 8, wherein the slot in the conductive clip is a continuous slot.

10. The semiconductor device assembly of claim 8, wherein the conductive clip includes an electrically conductive material that defines a surround of the slot.

11. The semiconductor device assembly of claim 8, further comprising a molding compound encapsulating the semiconductor die and the conductive clip, and at least partially encapsulating the substrate.

12. The semiconductor device assembly of claim 11, wherein:
a first portion of the molding compound is disposed between the conductive clip and the substrate, and
a second portion of the molding compound is disposed in the slot.

13. The semiconductor device assembly of claim 8, further comprising a leadframe including a power terminal, the conductive clip being further coupled to the power terminal.

14. The semiconductor device assembly of claim 13, wherein the leadframe further includes a signal terminal that is electrically coupled with the semiconductor die via a wire bond.

15. The semiconductor device assembly of claim 14, wherein:
the semiconductor die includes a field-effect transistor (FET);
the conductive clip is coupled with a source terminal of the FET;
a drain terminal of the FET is coupled with the substrate; and
the wire bond is coupled with a gate terminal of the FET.

16. A method for producing a semiconductor device assembly, the method comprising:
coupling a semiconductor die with a substrate;
coupling a conductive clip with the semiconductor die, the conductive clip including a slot defined therethrough, the slot having an area that is at least twenty percent of an area of a footprint of the conductive clip;
forming a wire bond with the semiconductor die;
applying an adhesion promoting material to the semiconductor die, the substrate, the conductive clip and the wire bond; and
performing a molding process to encapsulate the semiconductor die and the conductive clip in a molding compound, and at least partially encapsulate the substrate in the molding compound.

17. The method of claim 16, wherein applying the adhesion promoting material includes spraying the adhesion promoting material.

18. The method of claim 16, wherein applying the adhesion promoting material includes applying the adhesion promoting material to a portion of the substrate and a portion of the semiconductor die by spraying the adhesion promoting material through the slot.

19. The method of claim 16, further comprising coupling the conductive clip with a power terminal of a leadframe.

20. The method of claim 16, wherein forming the wire bond with the semiconductor die includes electrically coupling the semiconductor die with a signal terminal of a leadframe via the wire bond.
